(19) United States
(12) Patent Application Publication
(10) Pub. No.: US 2006/0220195 A1
(43) Pub. Date: Oct. 5, 2006

(54) Structure and method to control underfill

(75) Inventor: Sandeep B. Sane, Chandler, AZ (US)

Correspondence Address: SCHWABE, WILLIAMSON & WYATT, PACWEST CENTER, SUITE 1900, 1211 S.W. FIFTH AVE., PORTLAND, OR, 97204, US

(73) Assignee: Intel Corporation

(21) Appl. No.: 11/095,693

(22) Filed: Mar. 31, 2005

(51) Int. Cl. H01L 21/00; H01L 23/495

(52) U.S. Cl. 257/676; 257/678; 438/115; 257/E21.504

(57) ABSTRACT

A silicon die having a junction side being attachable to a substrate, a backside surface spaced from the junction side and an underfill control feature to prevent an underfill from settling above said backside surface is disclosed herein.

### TECHNICAL FIELD

Embodiments of the present invention relate generally to silicon dice, and more particularly to a die structure and method that reduces backside contamination.

### BACKGROUND

A silicon die may include a plurality of connections on one surface disposed to be attached to a substrate. An underfill may be used to fill in gaps between the silicon die and the substrate and may create fillets at the sides of the die. An underfill may also be used to protect the die by spreading forces that may be exerted on it while being attached to a substrate. Silicon dice are getting thinner.

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings.

FIG. 1 illustrates a possible problem recognized by the inventor that may occur wherein an underfill may get on to a backside of a die and contaminate the backside;

FIG. 2 illustrates a plan view in accordance with a first described embodiment of the present invention;

FIG. 3a illustrates a cross-sectional view taken at the line 3a-3a in FIG. 2 in accordance with the first described embodiment of the present invention;

FIG. 3b illustrates a cross-sectional view in accordance with a second described embodiment of the present invention;

FIG. 4 illustrates a cross-sectional view in accordance with a third described embodiment of the present invention;

FIG. 5 illustrates a cross-sectional view in accordance with a fourth described embodiment of the present invention;

FIG. 6 illustrates a cross-sectional view in accordance with a fifth embodiment of the present invention;

FIG. 7 illustrates a plan view in accordance with a sixth described embodiment of the present invention;

FIG. 8 illustrates a cross-sectional view taken at the line 8-8 of in FIG. 7 in accordance with the sixth described embodiment of the present invention;

FIG. 9 illustrates a cross-sectional view in accordance with a seventh described embodiment of the present invention;

FIG. 10 illustrates a cross-sectional view in accordance with an eighth described embodiment of the present invention;

FIG. 11 illustrates a cross-sectional view in accordance with a ninth described embodiment of the present invention;

FIG. 12 illustrates a cross-sectional view in accordance with a tenth described embodiment of the present invention;

FIG. 13 illustrates a partially schematic cross-sectional view in accordance with an eleventh described embodiment of the present invention;

FIG. 14 is a flow diagram illustrating a method in accordance with an embodiment of the invention;

FIG. 15 is a flow diagram illustrating a method in accordance with another embodiment of the invention; and

FIG. 16 is a flow diagram illustrating a method in accordance with another embodiment of the invention.

### DETAILED DESCRIPTION OF ILLUSTRATIVE EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made in alternate embodiments. Therefore, the following detailed description is not to be taken in a limiting sense, and the scope of embodiments in accordance with the present invention is defined by the appended claims and their equivalents.

The following description may include terms such as inner, outer, under, between, upward, downward, outward, inward, top, bottom, beyond, above, below and the like. Such terms are used for descriptive purposes only and are not to be construed as limiting in the description or in the appended claims. That is, these terms are terms that are relative only to a point of reference and are not meant to be interpreted as limitations but are, instead, included in the following description to facilitate understanding of the various aspects of the invention.

Embodiments of the present invention may be directed to:

FIG. 1 Illustrates a problem that has not been recognized before as a potential problem. The inventor has discovered that with a thin die underfill may get on the top of the die and contaminate the backside surface. A silicon die 10 is shown attached to a substrate 12. An underfill 14 is shown under the die and at the sides 16 where a fillet 18 of underfill 14 is formed. Underfill 14 may wick or otherwise move up and onto a backside surface 20 creating areas of contamination 22. The contamination 22 may make the backside surface 20 less effective at transferring heat to a thermal solution that may be placed adjacent to it to remove heat from the die 10.

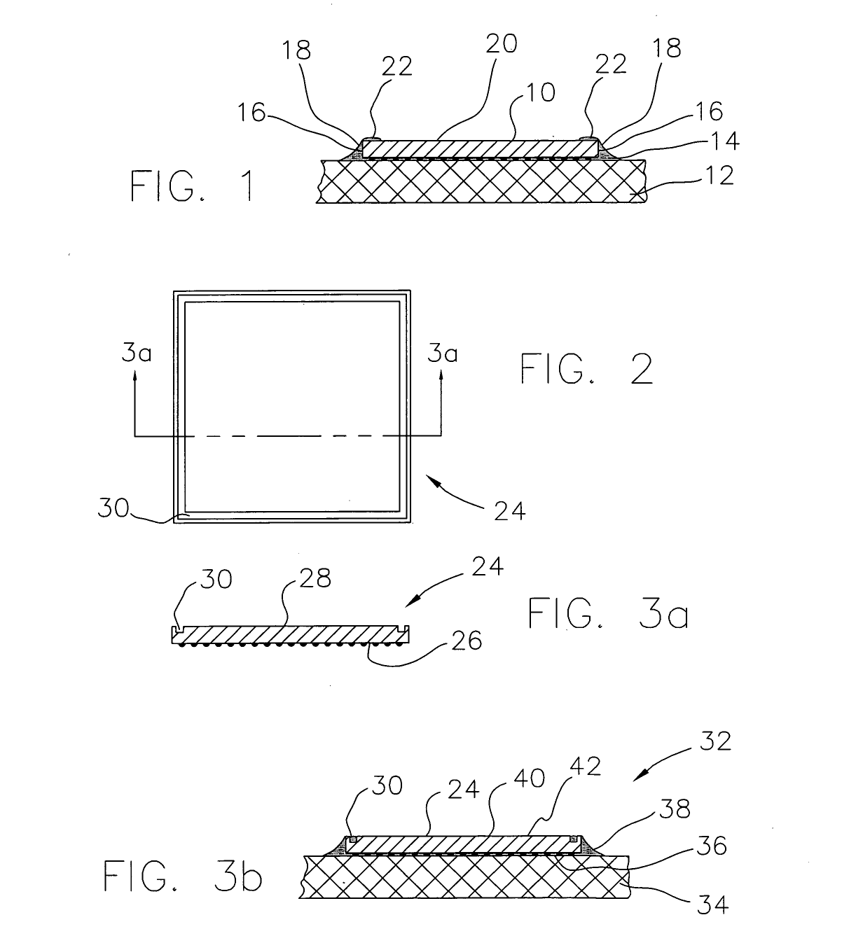

FIG. 2 illustrates a plan view of a first described embodiment of the invention and FIG. 3a illustrates a section taken along the line 3a-3a of FIG. 2. A silicon die 24 having a junction side 26 is attachable to a substrate. A backside surface 28 is spaced from the junction side 26. An underfill control feature 30 is cut, etched or otherwise formed into the die 24 to prevent an underfill from settling above or onto the backside surface 28. This embodiment shows how an underfill control feature 30 may be a channel 30 adjacent a perimeter of the die 24. The underfill control feature may be formed, in this embodiment or any other, in the backside surface by anisotropic etching, isotropic etching, laser etching, cutting, grinding, drilling or other means.

FIG. 3b is a cross sectional view and illustrates a second embodiment 32 of the invention wherein the silicon die 24 of FIG. 3a may be attached to a substrate 34 at a junction 36. An underfill 38 is prevented from settling above or onto a backside surface 40 which may be a thermal interface plane 40 by the underfill control feature 30. A backside metal BSM 42 may be added to the thermal interface plane 40 which may aide in thermal transfer. The BSM may be added before or after the underfill control feature 30 is formed in this, or any other, embodiment of the invention.

The underfill may be applied to a die/substrate junction after a die is attached, as may be the case when using capillary underfill (CUF). Capillary action may carry CUF under the die and up around the sides making a fillet joint. The underfill may also be applied onto a substrate before the die is attached, as may be the case when using no-flow underfill (NUF). NUF is applied to the substrate, then the die may be pressed into the NUF. Pressure and heat may be applied to attach the die to the substrate. The NUF may distend upward and the heat may make the NUF less viscous. The NUF may wick up onto the sides of the die side making a fillet joint. With any type of underfill an underfill control feature may be used to keep the underfill from moving onto the backside surface.

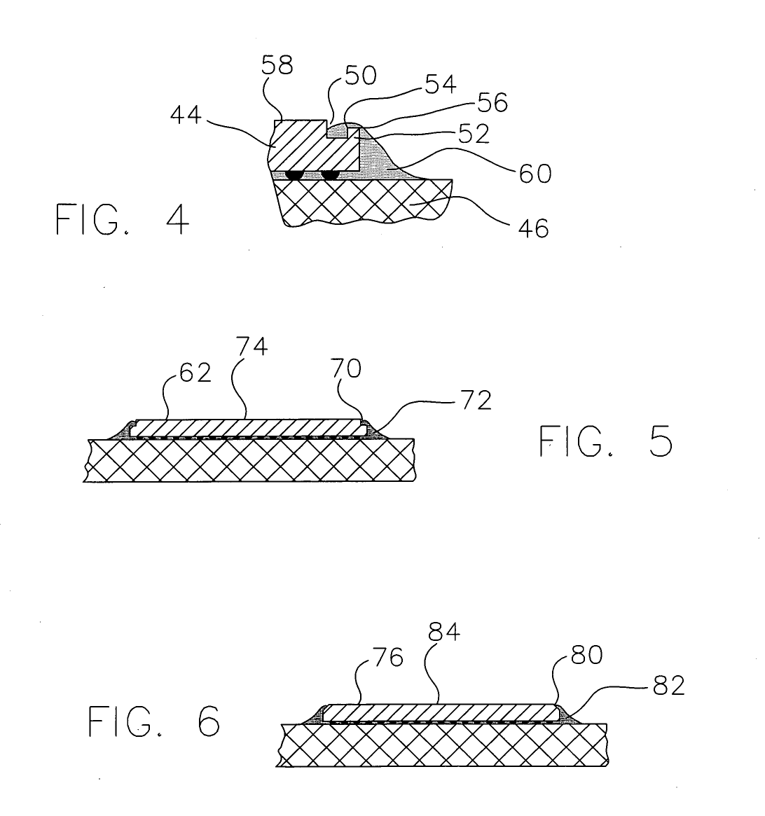

FIG. 4 is a cut away view expanded to show detail which illustrates a third embodiment of the invention wherein a silicon die 44 is attached to a substrate 46. An underfill control feature in the form of a channel 50 has a low wall 52 to define an outer edge 54 of the channel 50. The low wall 52 has a top edge 56 that may be lower than the backside surface 58. Underfill 60 that wicks, or otherwise moves, toward the backside is kept from settling onto, above or beyond the backside surface 58 by the channel 50.

FIG. 5 illustrates a fourth embodiment of the invention including a die 62 having an underfill control feature in the form of a notch 70 defined in at least a portion of a perimeter of the die 62. An underfill 72 is shown controlled or otherwise prevented from settling onto or above or beyond a backside surface 74.

FIG. 6 illustrates a fifth embodiment of the invention including a die 76 having an underfill control feature in the form of a chamfered edge 80 at least at a portion of a perimeter of the die. An underfill 82 is shown controlled or otherwise prevented from settling onto, above or beyond a backside surface 84.

When an underfill is applied at one side it may be more likely to wick onto only one side of the backside surface. An embodiment may include an underfill control feature on only a portion of the die, for example one side. An embodiment of the invention may include an underfill control feature on only a portion of one side, for example, in the form of a single cavity, or reservoir on only one side of the die.

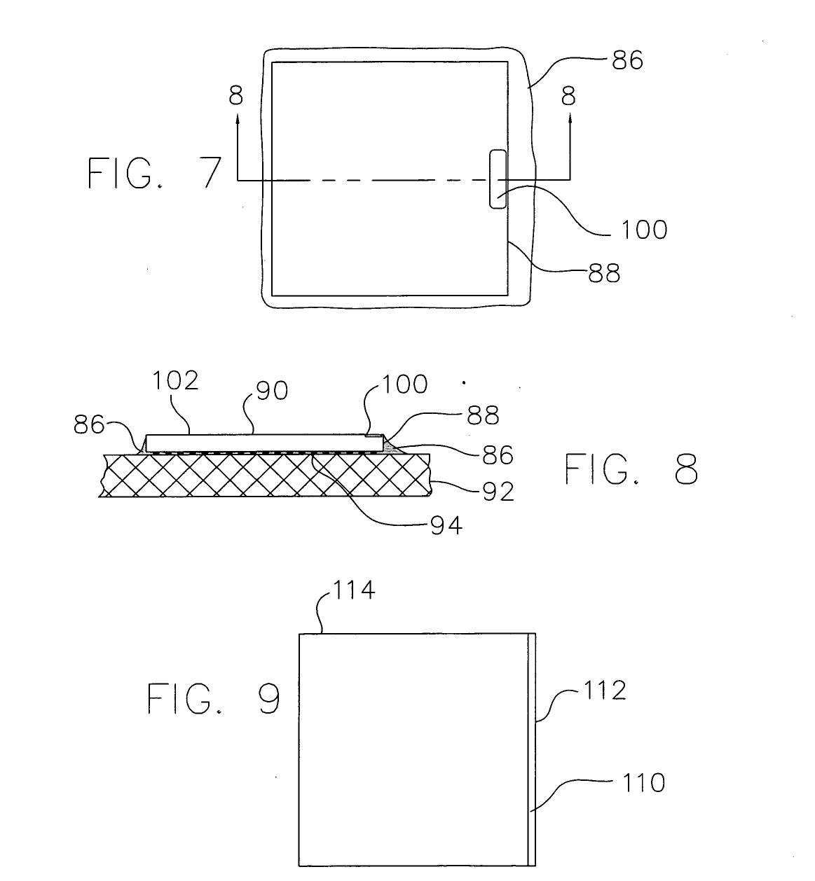

FIG. 7 is a top view and FIG. 8 is a cross sectional view taken at the line 8-8 of FIG. 7 illustrating a sixth embodiment of the invention which may be used with an underfill 86 that is applied adjacent one side 88 of a die 90 that has been attached to a substrate 92 at a junction 94 and arranged to wick under and around the edges of the die 90. An underfill control feature in the form of a single cavity 100 is etched, cut or otherwise formed into the backside surface 102 near one 88 side of the die 90.

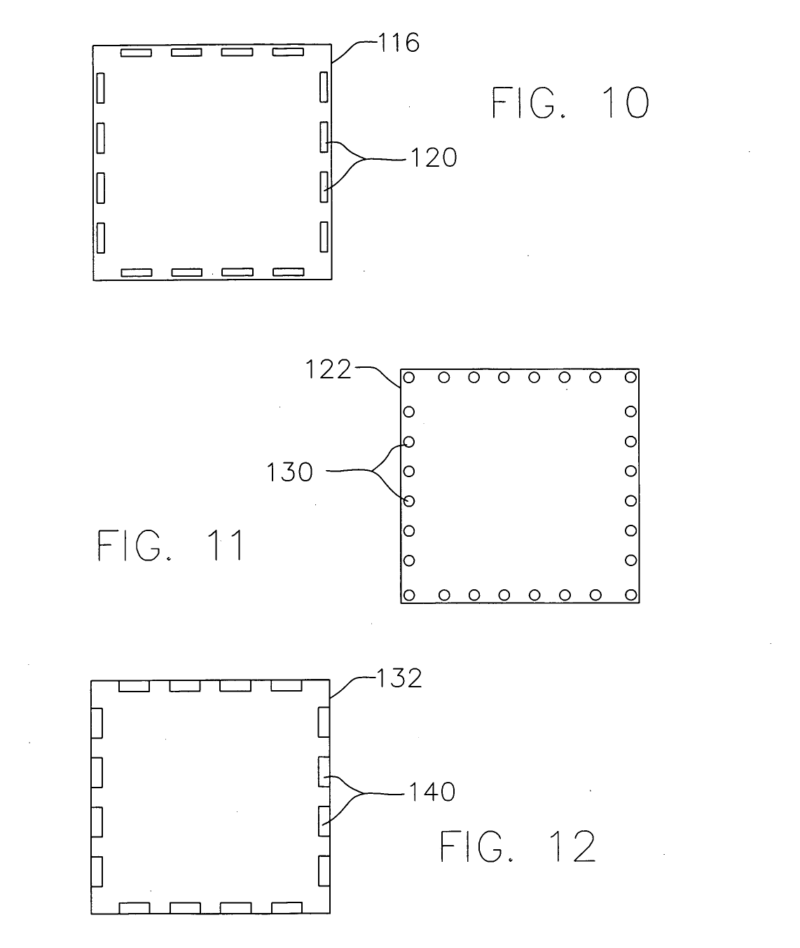

FIG. 9 illustrates a top view of seventh described embodiment of the invention. An underfill control feature is shown in the form of a notch 110 on one side 112 of a die 114.

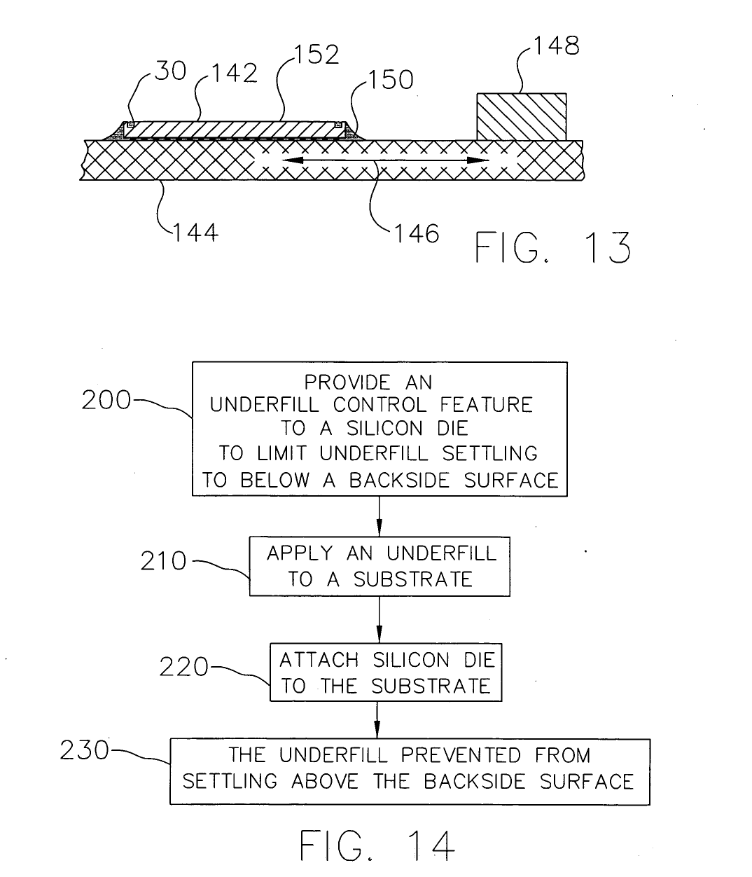

Various other embodiments of the invention are shown in FIGS. 10, 11, and 12. FIG. 10 illustrates a top view of an embodiment of a die 116 having an underfill control feature in the form of a plurality of channels or discontinuous channels 120 therein. FIG. 11 illustrates a top view of an embodiment of a die 122 having an underfill control feature in the form of a plurality of or series of holes 130 therein. FIG. 11 illustrates a top view of an embodiment of a die 132 having an underfill control feature in the form of a plurality of notches or a discontinuous peripheral notch 140. In each embodiment, as in the case of other embodiments, the feature can be formed in a die body by any suitable means.

Embodiments of the invention also allow less stringent volume control of an applied underfill volume as any overage amount can be controlled by an underfill control feature. An applied underfill volume has an upper volumetric tolerance being roughly from a quantity sufficient to underfill and create fillets at a minimum, to a quantity to underfill and create fillets and fill the underfill control feature at a maximum, the underfill volumetric tolerance may be controllable by an underfill control feature in embodiments of the invention.

FIG. 13 is a partially schematic cross sectional view illustrating another embodiment of the invention. A die 142 may be attached to a substrate 144 and may be coupled as represented by an arrow 146 with a volatile memory device 148 which may be, but is not limited to, DRAM and SRAM memory. An underfill 150 has been applied and is kept from settling above a backside surface 152 of the die 142 by an underfill control feature in the form of a channel 30.

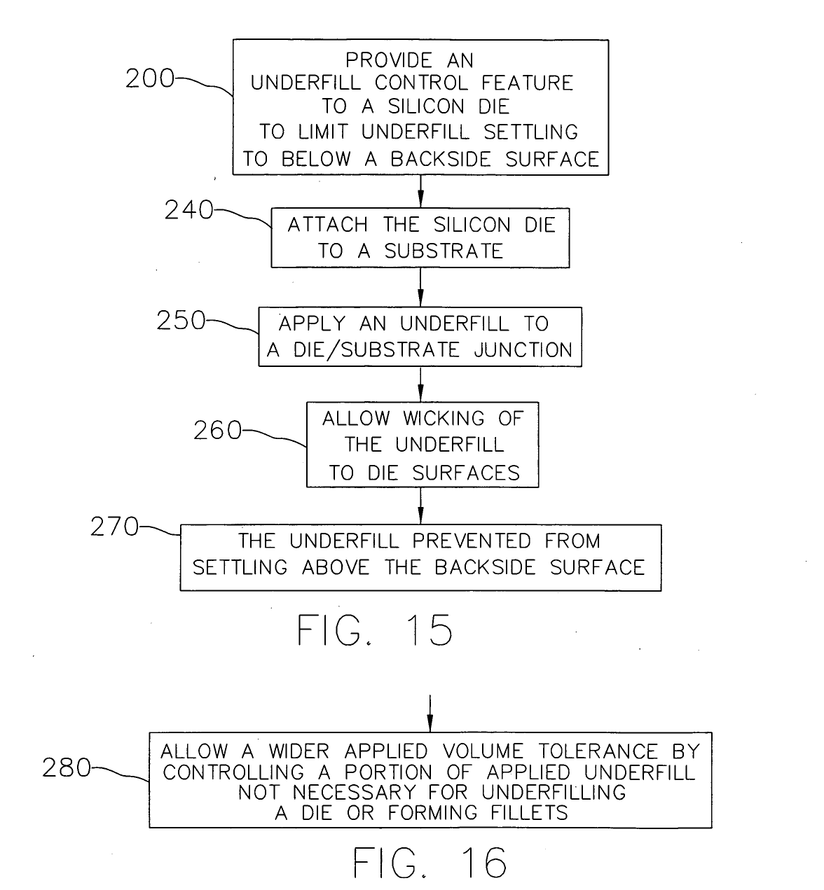

FIG. 14 is a flow diagram illustrating a method in accordance with an embodiment of the invention. The method includes, providing an underfill control feature capable of limiting any settling of an underfill to below a backside surface on a silicon die (200). A backside metal BSM may be provided before or after the underfill control feature is provided

FIG. 14 also shows further operations that may be taken with an embodiment of the invention including:

applying an underfill quantity to the surface of a substrate (210);

attaching the silicon die to the substrate by including e.g. pushing the die into the underfill (220); and

underfill that may wick or distend above the backside surface being prevented from settling above the backside surface by the underfill control feature (230).

FIG. 15 is a flow diagram illustrating a method in accordance with another embodiment of the invention. The method also includes, providing an underfill control feature capable of limiting any settling of an underfill to below a backside surface on a silicon die (200). This embodiment may also include:

attaching the silicon die to a substrate forming a junction (240):

applying an underfill near the junction (250);

allowing the underfill to wick to surfaces of the silicon die (260); and

underfill that may wick onto the backside surface of the die being prevented from settling on the backside surface by the underfill control feature (270).

FIG. 16 is a flow diagram illustrating a method in accordance with another embodiment of the invention. The method includes:

allowing a wider applied volume tolerance by controlling an underfill overage, the underfill overage being a portion of applied underfill not necessary for underfilling a die or forming fillets (280).

The figures show the backside surface on the top only for illustration purposes, and the word above may be used to illustrate a relative position also only for illustration. It should be understood the die, substrate, backside and other elements of each embodiment may be oriented in any direction. The proportions shown for all the described embodiments are also only for illustration and may be varied a little or a lot.

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

1. A silicon die comprising:
a junction side being attachable to a substrate;
a backside surface spaced from the junction side; and
an underfill control feature to substantially prevent an underfill from settling above said backside surface.

2. The silicon die of claim 1 wherein said underfill control feature comprises a channel defined on said backside surface adjacent a perimeter of the silicon die.

3. The silicon die of claim 2 wherein an outer edge of said channel is defined by a low wall having a top edge, said top edge being lower than said backside surface.

4. The silicon die of claim 2 wherein said channel is continuous.

5. The silicon die of claim 2 wherein said channel is discontinuous.

6. The silicon die of claim 1 wherein said underfill control feature comprises at least one cavity defined in said backside surface sufficiently sized to hold an underfill volume below said backside surface.

7. The silicon die of claim 1 wherein said underfill control feature comprises a series of holes defined in the backside surface.

8. The silicon die of claim 1 wherein said underfill control feature comprises a notch defined at least at a portion of the perimeter of the silicon die.

9. The silicon die of claim 1 wherein said underfill control feature comprises a chamfer defined on said backside surface.

10. The silicon die of claim 1 wherein said underfill control feature comprises a series of notches defined at the perimeter of the silicon die.

11. The silicon die of claim 1 wherein said underfill control feature comprises a cavity defined in said backside surface cut into said backside surface by one from the group consisting of: anisotropic etching, isotropic etching, laser etching, cutting, grinding and drilling.

12. The silicon die of claim 1 wherein said silicon die is attached to the substrate at a junction, the underfill comprises a capillary underfill applied near said junction, said capillary underfill being wickable on surfaces of the silicon die including said backside surface.

13. The silicon die of claim 1 wherein said underfill comprises a no-flow underfill applied to a surface of a substrate, the silicon die being attachable to the substrate by being pushed into said no-flow underfill.

14. A method comprising:
providing an underfill control feature to a silicon die, the underfill control feature being capable of limiting settling of a underfill to below a backside surface on the silicon die;
applying an underfill quantity to the surface of a substrate.

15. The method of claim 14, wherein the providing of the underfill control feature comprises etching a channel into a backside of the silicon die, the channel being the underfill control feature.

16. The method of claim 14 wherein said providing a control feature includes forming one from the group consisting of:
a continuous perimeter channel;
a discontinuous perimeter channel;
a notch;
a chamfer;
a series of holes;
a single cavity; and
a series of notches.

17. The method of claim 14 wherein said providing an underfill control feature includes one selected from the group consisting of: anisotropic etching, isotropic etching, laser etching, cutting, grinding and drilling.

18. The method of claim 14 further comprising:
attaching the silicon die to a substrate by including pushing the die into the underfill;
limiting a volume of the applied quantity of underfill wicked or distended above the backside surface from remaining beyond the backside surface with the underfill control feature.

19. The method of claim 18 further comprising positioning a thermal solution adjacent to the backside surface.

20. The method of claim 14 further comprising:
attaching the silicon die to a substrate forming a junction;
applying the underfill near the junction;
allowing the underfill to wick to surfaces of the silicon die;
limiting the underfill movement with the underfill control feature.

21. The method of claim 20 further comprising positioning a thermal solution adjacent the backside surface.

22. The method of claim 14 further comprising:
applying a backside metal (BSM) before or after said providing an underfill control feature.

23. The method of claim 14 further comprising: controlling an underfill overage, said underfill overage being a portion of applied underfill not necessary for underfilling a die or forming fillets.

24. A system comprising:
a substrate;
a silicon die attached to said substrate at a junction, said silicon die having a backside surface having a thermal interface plane;
a DRAM memory device coupled with the silicon die;
an underfill control feature on said backside surface; and
an underfill near said junction being substantially prevented from settling beyond said thermal interface plane by said underfill control feature.

25. The system of claim 24 wherein providing a control feature includes forming one from the group consisting of:
a continuous perimeter channel;
a discontinuous perimeter channel;
a notch;
a chamfer;
a series of holes;
a single cavity; and
a series of notches.
